(19) United States
(12) Patent Application Publication
(10) Pub. No.: US 2003/0124451 A1
(43) Pub. Date: Jul. 3, 2003

(54) Method and apparatus for producing identification cards using photosensitive media employing microcapsules

(76) Inventors: Joseph C. Camillus, Centerville, OH (US); Alexander Y. Polykarpov, Mason, OH (US); Ibrahim Katampe, Kettering, OH (US)

Correspondence Address: THOMPSON HINE L.L.P., 2000 COURTHOUSE PLAZA , N.E., 10 WEST SECOND STREET, DAYTON, OH, 45402, US

(21) Appl. No.: 10/290,081

(22) Filed: Nov. 7, 2002

Related U.S. Application Data
(60) Provisional application No. 60/345,864, filed on Nov. 7, 2001.

(51) Int. Cl. G03C 5/56; G03C 8/08; G03C 8/34; G03C 8/40; G03C 11/14; G03F 7/027; G03F 7/028; G03F 7/09; G03F 7/105; G03F 7/26; G03B 13/00; G03D 9/02; G03D 5/06; G03D 5/00

(52) U.S. Cl. 430/138; 430/10; 430/203; 430/207; 430/211; 430/235; 430/334; 430/432; 430/404; 396/575; 396/583; 396/606; 396/611

(57) ABSTRACT

A method and apparatus for producing identification (ID) cards using a photosensitive imaging system employing microcapsules is described. In accordance with one aspect of the invention, ID cards are produced by translating an image containing identifying indicia into a latent image on an appropriate photosensitive donor sheet, pressure developing the latent image, forming a full color print of the image on a developer sheet, laminating an ID card substrate in registration with the image to the developer sheet and die cutting the laminated article to produce an ID card. Self-contained imaging systems can also be used to produce identification cards. The image preferably includes unique information useful in identifying the card holder such as a photograph, fingerprint, signature, description, name, etc. The identifying indicia may be combined with non-variable information including background printing, card issuer data, logos, security features, etc. An ID card produced in accordance with certain embodiments of the present invention provides a secure identification card which is inherently more durable and less susceptible to delamination and tampering because the image is directly laminated to the ID card substrate.

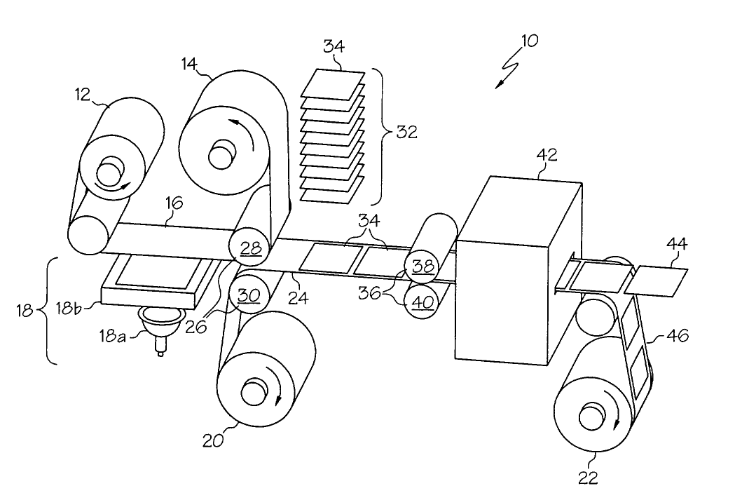

### CROSS REFERENCE TO RELATED APPLICATION

This application claims priority from U.S. Provisional Application Serial No. 60/345,864 filed Nov. 7, 2001.

### BACKGROUND OF THE INVENTION

The present invention generally relates to a method and apparatus for producing identification (ID) cards using a photosensitive imaging system employing microcapsules. In accordance with one aspect of the invention, ID cards are produced by translating an image containing identifying indicia into a latent image on an appropriate photosensitive donor sheet, pressure developing the latent image, forming a full color print of the image on a developer sheet, laminating an ID card substrate in registration with the image to the developer sheet and die cutting the laminated article to produce an ID card. The image preferably includes unique information useful in identifying the card holder such as a photograph, fingerprint, signature, description, name, etc. The identifying indicia may be combined with non-variable information including background printing, card issuer data, logos, security features, etc. An ID card produced in accordance with certain embodiments of the present invention provides a secure identification card which is inherently more durable and less susceptible to delamination and tampering because the image is directly laminated to the ID card substrate.

The photosensitive imaging system useful in accordance with the present invention employs microcapsules containing a photosensitive composition in the internal phase. Photosensitive imaging systems employing microencapsulated radiation sensitive compositions are the subject of U.S. Pat. Nos. 4,399,209; 4,416,966 and 4,440,846. These imaging systems are characterized in that an imaging sheet including a layer of microcapsules containing a photosensitive composition in the internal phase is image-wise exposed to actinic radiation. In the most typical embodiments, the photosensitive composition is a photopolymerizable composition including a polyethylenically unsaturated compound and a photoinitiator and is encapsulated with a color former. The exposure image-wise hardens the internal phase of the microcapsules. Following exposure, the imaging sheet is subjected to a uniform rupturing force by passing the sheet through the nip between a pair of pressure rollers. U.S. Pat. No. 4,399,209 discloses a transfer system in which the imaging sheet is assembled with a developer sheet prior to being subjected to the rupturing force. Upon passing through the pressure rollers in contact with the developer sheet, the microcapsules image-wise rupture and release the internal phase whereupon the color former migrates to the developer sheet where it reacts with a developer and forms a color image. The imaging system can be designed to reproduce monochromatic, polychromatic or full color images.

Identifying information for the ID card may be collected by using a scanner, camera, video camera, digital camera, personal computer including a keyboard, mouse or other image or data input device. Imaging systems for recording an image from a video signal are well known and described, for example, in U.S. Pat. Nos. 5,140,428 and 5,223,960 to Goldstar, U.S. Pat. Nos. 5,128,773 and 5,189,468 to Fuji, U.S. Pat. No. 4,935,820 to 3M and U.S. Pat. No. 4,816,846 to AT&T. Such patents generally teach the use of a liquid crystal display (LCD) and/or a cathode ray tube (CRT) to produce a latent image on a photosensitive medium.

### SUMMARY OF THE INVENTION

The present invention relates to a method and apparatus for producing identification (ID) cards using a photosensitive imaging system employing microcapsules. In accordance with one aspect of the invention, identification cards are produced by a method comprising the steps of:

(a) providing a photosensitive imaging media comprising a developer material and a plurality of microcapsules encapsulating a photohardenable composition and a color former;

(b) image-wise exposing the plurality of microcapsules to actinic radiation to form a latent image;

(c) developing the image; and

(d) laminating an ID card substrate to the image to form an identification card comprising an image, wherein the image contains identifying information.

In accordance with another embodiment of the present invention, an image containing identifying indicia is translated into actinic radiation capable of image-wise exposing a suitable photosensitive donor imaging sheet, the exposed donor sheet is developed to provide a full color print of the image on the developer sheet, an ID card substrate in registration with the image is laminated to the developer sheet and the laminated article is die cut to produce an ID card. The present invention is particularly advantageous where a photosensitive layer comprising microcapsules containing a photosensitive composition in the internal phase is image-wise exposed to actinic radiation and subjected to a uniform rupturing force whereupon the microcapsules rupture and image-wise release the internal phase which reacts with a developer material to produce an image therein. The image, containing identifying information, is preferably protected by laminating an ID card substrate to the image bearing surface of the developer sheet. Finished ID cards are produced by die cutting the laminated article to the desired dimensions.

According to yet another embodiment of the invention, there is described a method for producing identification cards using a photosensitive imaging system containing microcapsules, the method comprising the steps of image-wise exposing a photosensitive pressure-sensitive donor sheet to actinic radiation to form a latent image thereon, juxtaposing the donor sheet to a developer sheet, subjecting the juxtaposed sheets to pressure to develop the latent image, thereby forming a full color print of the image on the developer sheet, laminating an ID card substrate in registration with the image to the developer sheet and die cutting the laminated article to produce a finished ID card comprising a full color image containing identifying information regarding the cardholder.

In accordance with another embodiment of the invention, an apparatus for producing ID cards is described. The apparatus comprises: an exposure means for image-wise exposing a photosensitive donor sheet to actinic radiation to form a latent image thereon, the image comprising personalized information; a pressure developer means for pressure developing the latent image on the exposed donor sheet and forming an image on a developer sheet; lamination means for laminating an ID card substrate in registration with the image to the developer sheet; and a die for die cutting the laminated article to produce a finished ID card.

Particular aspects of the invention will become apparent from the following description and the accompanying drawing.

### BRIEF DESCRIPTION OF THE DRAWING

The FIGURE is a schematic diagram of an apparatus for making an ID card according to one embodiment of the present invention.

### DETAILED DESCRIPTION OF THE INVENTION

All documents cited are, in relevant part, incorporated herein by reference; the citation of any document is not to be construed as an admission that it is prior art with respect to the present invention.

The ID system of the present invention utilizes an apparatus that has a small footprint and can be used to generate photograph-like quality ID cards quickly and on-site. Typical examples of ID card applications include bank cards (e.g., credit cards, debit cards, etc), driving licenses, national ID cards, student ID cards, passports, clearance cards, smart cards, etc. ID cards prepared in accordance with certain embodiments of the present invention are advantageous in that the image is directly laminated to the ID card substrate. Any attempt at tampering or alteration would destroy the personalized information as well as the background information that identifies the cardholder. Since the personalized information is a part of the laminate structure, the photographic image cannot be removed and replaced without destroying the card because the image on the developer sheet is directly laminated to the ID card substrate.

Referring to the accompanying drawing, a detailed description will be given for an apparatus and method for producing a secure ID card using a photosensitive media.

The FIGURE is a diagrammatic side view of an apparatus 10 for making an ID card in accordance with the present invention. The apparatus 10 includes a donor unwind 12 and a donor rewind 14, wherein a photosensitive donor sheet 16, in the form of a continuous web, rolled around the donor unwind 12 is unrolled and is conveyed along a path and is rewound on donor rewind 14.

An exposure unit 18 is disposed downstream of the donor unwind 12 with respect to the direction in which the donor sheet 16 is conveyed, wherein the donor sheet 16 is image-wise exposed to actinic radiation preferably corresponding to a digitized image containing personalized information. The exposure unit 18 in the FIGURE includes a light source 18a and a source image 18b wherein light emitted from the light source 18a passes through the source image 18b to illuminate the photosensitive donor sheet 16. In accordance with other embodiments, the exposure unit may include various devices for directly image-wise exposing the donor sheet to actinic radiation. Examples of actinic radiation sources include, but are not limited to, LED's, liquid crystal arrays, electroluminescent lamps, light emitting plasma and laser devices and other light emitting elements.

Apparatus 10 also includes a developer unwind 20 and a developer rewind 22, wherein a developer sheet 24, in the form of a continuous web, rolled around the developer unwind 20 is unrolled and is conveyed along a path and is rewound on developer rewind 22. Disposed downstream of the exposure unit 18 is a pressure developing unit 26 comprising a pair of developer rollers 28, 30. The developer rollers 28, 30 bring the donor sheet 16 into facial contact with the developer sheet 24 and subject the donor sheet 16 and developer sheet 24 to a uniform rupturing force whereupon the photosensitive microcapsules in the donor sheet rupture and image-wise release the internal phase which reacts with the developer material to produce an image on the developer sheet 24. The donor sheet 16 is conveyed along a path around developer roller 28 and is rewound on donor rewind 14.

The developer sheet 24 with a visible image therein is conveyed along a path around developer roller 30 in a direction toward the developer rewind 22. In the conveying path of the developer sheet 24, an ID card substrate feed system 32 is disposed for feeding ID card substrate 34 to the imaged surface of the developer sheet 24 in registration with the visible image. Downstream of the ID card substrate feed system 32 is a lamination unit 36 for laminating ID card substrate 34 on the image formed surface of the developer sheet 24 to produce a laminated article. The lamination unit 36 comprises a pair of laminating rollers 38, 40 having a nip therebetween allowing passage of the ID card substrate 34 and the developer sheet 24 therethrough when the rollers 38, 40 are rotated. The laminating rollers 38, 40 may be heated to facilitate lamination or, in the case of thermosetting or thermoplastic adhesives, cause activation of the adhesive. Alternatively, a preheat unit may be provided before the lamination unit to heat the ID card substrate and developer sheet to the desired temperature. Heating of the media with a preheat unit can be accomplished using an oven, heated forced air, IR, thermal head, heating strip or plate, etc. In cases where the imaging media is heated during lamination to activate a thermally activated adhesive, the media is typically laminated at a temperature of from about 70° C. to 125° or higher, preferably around 100° C.

Disposed downstream of the lamination unit 36 is a die cutter 42 for die cutting the laminated article comprising the ID card substrate 34 and the imaged developer sheet 24 to produce finished ID cards 44 of the desired dimensions which are separated from the developer matrix 46 which is rewound on developer rewind 22. Preferably, the ID card substrate 34 as supplied to the ID card feed system 32, is precut to the appropriate dimensions for the finished ID card such that the die cut operation is limited to precision cutting of the developer sheet 24 to the same dimensions as the ID card substrate 34. In accordance with a preferred embodiment of the present invention, the developer sheet comprises a clear coating of developer material on a transparent substrate, preferably light-transmissive polyester or polyolefin such as polypropylene, polyethylene, etc. Accordingly, the image on the ID card can be viewed through the developer sheet against the ID card substrate backing. The image is sandwiched between the ID card substrate and the developer sheet thereby providing protection for the image against elements which could damage the image as well as producing a secure ID card which is resistant to tampering and alteration.

The exposure producing elements useful in this invention are any elements or other sources of radiation which are capable of producing modulated light in an array of colors or the light from the exposure producing elements such as light emitting diodes, liquid crystal display panels or projectors, cathode ray tubes, fiber optics, lasers, light bulbs, etc. may pass through a color producing element, e.g., lenses, crystals, LCD's, etc. The light from the exposure producing elements may be time modulated, intensity modulated, etc. to produce any number or variety of colors. Preferably, the light producing elements are time modulated LED's and, most preferably, colored LED's. Satisfactory colored prints have been obtained using red, green and blue LED's.

The imaging system described above is especially suitable for use in the present invention for exposure using a liquid crystal array or light emitting diodes driven by an electronic signal for the reproduction of images from a computer, digital camera, camera, scanner, video cassette recorder, camcorder, or the like. Personalized or identifying information and background information may be captured and processed using a variety of techniques. A Charge Couple Device (CCD) scanner may be used to capture signatures, logos, fingerprints, etc., a video camera may be used to capture a photograph and a keyboard, mouse or other input device may be used to enter related data such as date of birth, age, height, etc. The information from all of the devices may be captured and converted into one or more digital images for output to the photosensitive imaging system.

The ID card substrate may comprise any material typically used for construction of ID cards. The substrate may be transparent or reflective. Examples of ID card substrates useful in the present invention include polycarbonate, polyvinyl chloride, polyethylene, polystyrene, polyester, synthetic papers, etc. Preferably, the ID card substrate is precoated with a laminating adhesive which bonds to the developer sheet under heat and/or pressure to produce the laminated card of the invention. In a preferred embodiment, the adhesive is applied over substantially the entire face of the ID card substrate to securely adhere the substrate to the developer sheet. Preferred adhesives include pressure sensitive and thermally activated (thermosetting or thermoplastic adhesives). Specific examples of pressure sensitive adhesives include hot melts, water borne, solvent borne, etc. Preferred examples of pressure sensitive adhesives include acrylics such as 300 adhesive from 3M Company, S2001 from Avery Dennison. Examples of commercially available thermally activated adhesives include Waytek W60 and W35 and Dow Chemical Integral 801 and DAF-709. These thermally activated adhesives are advantageous because they are non-tacky at room temperatures and become tacky at or above the activation temperature typically from about 70° C. to 125° or higher, preferably around 100° C. Accordingly, ID card substrates with a thermally activated adhesive can be stacked without blocking or sticking together, thereby facilitating processing and handling. UW and EB curable adhesives may also be useful. A preferred example of a UV curable hot melt pressure sensitive adhesive is RC 21151 from Novamelt Company.

The photosensitive imaging system useful in accordance with one aspect of the present invention employs a transfer imaging system comprising a donor sheet and a developer sheet. The donor sheet is coated with a composition including microcapsules containing a photosensitive composition in the internal phase. These imaging systems are characterized in that an imaging sheet including a layer of microcapsules containing a photosensitive composition in the internal phase is image-wise exposed to actinic radiation. In the most typical embodiments, the photosensitive composition is a photopolymerizable composition including a polyethylenically unsaturated compound and a photoinitiator and is encapsulated with a color former. The exposure image-wise hardens the internal phase of the microcapsules. Following exposure, the donor sheet, in contact with a developer sheet, is subjected to a uniform rupturing force by passing the sheets in facing relationship through the nip between a pair of pressure rollers. Upon passing through the pressure rollers in contact with the developer sheet, the microcapsules image-wise rupture and release the internal phase whereupon the color former migrates to the developer sheet where it reacts with a dry developer and forms a color image. The imaging system can be designed to reproduce monochromatic, polychromatic or full color images.

The photosensitive imaging system in accordance with another embodiment of the present invention may be a self-contained imaging system comprising a support and an imaging layer containing photosensitive microcapsules and a developer material. In accordance with this embodiment, the photosensitive imaging media may be embodied in a self-contained copy sheet in which the encapsulated chromogenic material and the developer material are co-deposited on one surface of a single support as one layer or as two interactive layers or they are deposited on two supports in layers which can interact when the supports are juxtaposed. The self-contained sheet may have a protective coating on the surface of the imaging layer as described in U.S. patent application Ser. No. 09/761,014 filed Jan. 16, 2001. In the case of a self-contained sheet, the self-contained sheet is imagewise exposed to actinic radiation and the image developed by passing the self-contained sheet through the pressure developing unit 26 comprising a pair of developing rollers 28, 30. The image develops on the self-contained sheet. Since a separate developer sheet is not required, the self-contained sheet basically follows the path of the donor sheet in the FIGURE.

Lamination of the self-contained image to the ID card substrate may be effected by providing the ID card substrate with a laminating adhesive or by providing an adhesive layer on the surface of the self-contained sheet. In accordance with one embodiment, the self-contained sheet includes a thermally activated (thermosetting or thermoplastic) adhesive layer overlying the imaging layer. The thermosetting or thermoplastic adhesive layer is not tacky until heated to the activation temperature for the adhesive and may function as a protective coating for the imaging layer prior to activation.

The imaging systems of the present invention utilize microcapsules to carry the image forming components. The operational center of the imaging system is the encapsulate or internal phase of the coating composition. The internal phase comprises a chromogenic material and a photohardenable composition.

The internal phase preferably includes a diisocyanate or polyisocyanate compound which functions as a pre-wall reactant. As is known in the art, the polyisocyanate compound is capable of reacting with the water from the aqueous phase by polycondensation to form a thin layer of a polyurea polymer around the internal phase. A particularly preferred polyisocyanate is Desmodur N-100, a biuret of hexamethylene diisocyanate and water available from Mobay Chemical Company. Other isocyanates, such as SF-50, manufactured by Union Carbide may be used in this invention. The polyisocyanate is typically added in an amount of about 2 to 15 parts per 100 parts of internal phase.

Typically, the photosensitive composition includes a photoinitiator and a substance which undergoes a change in viscosity upon exposure to light in the presence of the photoinitiator. That substance may be a monomer, dimer, oligomer or mixture thereof which is polymerized to a higher molecular weight compound or it may be a polymer which becomes cross-linked.

Typically, the substance which undergoes a change in viscosity is a free radical addition polymerizable or crosslinkable compound. The most typical example of a free radical addition polymerizable or crosslinkable compound useful in the present invention is an ethylenically unsaturated compound and, more specifically, a polyethylenically unsaturated compound. These compounds include both monomers having one or more ethylenically unsaturated groups, such as vinyl or allyl groups, and polymers having terminal or pendant ethylenic unsaturation. Such compounds are well known in the art and include acrylic and methacrylic esters of polyhydric alcohols such as trimethylolpropane, pentaerythritol, and the like; and acrylate or methacrylate terminated epoxy resins, acrylate or methacrylate terminated polyesters, etc. Representative examples include ethylene glycol diacrylate, ethylene glycol dimethacrylate, trimethylolpropane triacrylate (TMPTA), pentaerythritol tetraacrylate, pentaerythritol tetramethacrylate, dipentaerythritol hydroxypentacrylate (DPHPA), hexanediol-1,6-dimethacrylate, and diethylene glycol dimethacrylate.

The radiation curable or depolymerizable material usually makes up the majority of the internal phase. A radiation curable material must be present in an amount sufficient to immobilize the chromogenic material upon exposure. Typically these materials constitute 40 to 99 wt % of the internal phase (based on the weight of the oil solution containing the chromogen, the photosensitive composition and the carrier oil when present).

In some embodiments, it has been found desirable to dilute the photosensitive composition with a carrier oil to improve half-tone gradation. In these cases a carrier oil is present in the amounts disclosed below and the aforesaid materials make up to 40 wt % of the internal phase.

The chromogenic materials used in the present invention are those chromogenic materials conventionally used in carbonless paper. In general, these materials are colorless electron donating type color formers which react with a developer compound to generate a dye. Representative examples of such color formers include substantially colorless compounds having in their partial skeleton a lactone, a lactam, a sultone, a spiropyran, an ester or an amido structure. Specifically, there are triarylmethane compounds, bisphenylmethane compounds, xanthene compounds, thiazine compounds, spiropyran compounds and the like. Typical examples of useful color formers include Crystal Violet lactone (CVL), benzoyl leuco methylene blue (BLMB), Malachite Green Lactone, p-nitrobenzoyl leuco methylene blue, 3-dialkylamino-7-dialkylamino-fluoran, 3-methyl-2,2′-spirobi(benzo-f-chrome), 3,3-bis(p-dimethylaminophenyl)phthalide, 3-(p-dimethylaminophenyl)-3-(1,2dimethylindole-3-yl)phthalide, 3-(p-dimethylaminophenyl)-3-(2-methylindole-3-yl)phthalide, 3-(p-dimethylaminophenyl)-3-(2-phenylindole-3-yl)phthalide,3,3-bis(1,2-dimethylindole-3-yl)-5-dimethylaminophthalide, 3,3-bis-(1,2-dimethylindole-3-yl)6-dimethylaminophthalide, 3,3-bis-(9-ethylcarbazole-3-yl)-5-dimethylaminophthalide, 3,3-bis(2-phenylindole-3-yl)-5-dimethylaminophthalide, 3-p-dimethylaminophenyl-3-(1-methyl pyrrole-2-yl)-6-dimethylaminophthalide, 4,4′-bis-dimethylaminobenzhydrin benzyl ether, N-halophenyl leuco Auramine, N-2,4,5-trichlorophenyl leuco Auramine, Rhodamine-B-anilinolactam, Thodamine(p-nitroanilino)lactam, Rhodamine-B-(p-chloroanilino)lactam, 3-dimethylamino-6-methoxyfluoran, 3-diethylamino-7-methoxyfluoran, 3-diethylamino-7-chloro-6-methylfluoroan, 3-diethylamino-6-methyl-7-anilinofluoran, 3-diethylamino-7-(acetylmethylamino)fluoran, 3-diethylamino-7-(dibenzylamino)fluoran, 3-diethylamino-7-(methylbenzylamino)fluoran, 3-diethylamino-7-(chloroethylmethylamino)fluoran, 3-diethylamino-7-(diethylamino)fluoran, 3-methyl-spiro-dinaphthopyran, 3,3′-dichloro-spiro-dinaphthopyran, 3-benzyl-spiro-dinaphthopyran, 3-methyl-naphtho-(3-methoxybenzo)-spiropyran, 3-propyl-spirodibenzoidipyran, etc. Mixtures of these color precursors can be used if desired. Also useful in the present invention are the fluoran color formers disclosed in U.S. Pat. No. 3,920,510, which is incorporated by reference. In addition to the foregoing dye precursors, fluoran compounds such as disclosed in U.S. Pat. No. 3,920,510 can be used. In addition, organic compounds capable of reacting with heavy metal salts to give colored metal complexes, chelates or salts can be adapted for use in the present invention.

In accordance with the invention, the chromogenic material is incorporated in the internal phase in an amount sufficient to produce a visible image of the desired density upon reaction with the developer. In general, these amounts range from approximately 0.5 to about 20.0 percent based on the weight of the internal phase solution (e.g., monomer or monomer and oil) containing the chromogen. A preferred range is from about 2 percent to about 10 percent. The amount of the chromogenic material required to obtain suitable images depends on the nature of the chromogen, the nature of the internal phase, and the type of imaging system. Typically less chromogenic material is used in the internal phase of a self-contained imaging system in comparison to a transfer system. This is because the developer material is co-deposited on a common substrate with the chromogenic encapsulate and there is a tendency for the chromogenic material to diffuse through the capsule wall and react with the developer material during storage and because there is no inherent loss in transfer.

In addition to the chromogenic material and the photosensitive material, the internal phase of the present invention may also include a carrier oil to affect and control the tonal quality of the images obtained. While tonal quality (half-tone gradation) is not critical when copying printed documents, it is an important factor in faithfully reproducing pictorial images. In some cases where trimethylolpropane triacrylate is used in the radiation curable material, 20% of a carrier oil such as brominated paraffin improves tonal qualities. Preferred carrier oils are weakly polar solvents having boiling points above 170° C. and preferably in the range of 180° C. to 300° C. The carrier oils used in the present invention are typically those conventionally used in carbonless paper manufacture. These oils are generally characterized by their ability to dissolve Crystal Violet Lactone in a concentration of 0.5 wt % or more. However, a carrier oil is not always necessary. Whether a carrier oil should be used will depend on the solubility of the chromogenic material in the photosensitive composition before exposure, the nature of the chromogenic material and the viscosity of the characteristics of the internal phase. When present, examples of carrier oils are alkylated biphenyls (e.g., monoisopropylbiphenyl), polychlorinated biphenyls, castor oil, mineral oil, deodorized kerosene, naphthenic mineral oils, dibutyl phthalate, dibutyl fumerate, brominated paraffin and mixtures thereof. Alkylated biphenyls are generally preferred.

Various photoinitiators can be selected for use in the present invention. These compounds absorb the exposure radiation and generate a free radical alone or in conjunction with a sensitizer. Conventionally, there are homolytic photoinitiators which cleave to form two radicals and initiators which radiation converts to an active species which generates a radical by abstracting a hydrogen from a hydrogen donor. There are also initiators which complex with a sensitizer to produce a free radical generating species and initiators which otherwise generate radicals in the presence of a sensitizer. Both types can be used in the present invention. If the system relies upon ionic polymerization to tie up the chromogen, the initiator may be the anion or cation generating type depending on the nature of the polymerization. Where, for example, ultraviolet sensitivity is desired, as in the case of direct transmission imaging using ultraviolet light, suitable photoinitiators are described in the aforementioned patents. The sensitivity among these compounds can be shifted by adding substituents such that the compounds generate radicals when exposed to the desired radiation wavelength.

The photoinitiator is present in the internal phase in an amount sufficient to initiate polymerization or cross-linking within a short exposure time. Using benzoin methyl ether as an example, this photoinitiator is typically present in an amount of up to 10% based on an amount of radiation curable material in the internal phase. Naturally, the amount varies depending on the nature of the other components of the photosensitive composition.

Particularly useful as photoinitiators in the present invention are cationic dye-borate anion complexes as disclosed in commonly assigned U.S. Pat. Nos. 5,112,752; 5,100,755; 5,057,393; 4,865,942; 4,842,980; 4,800,149; 4,772,530 and 4,772,541 which are incorporated herein by reference. When employed as a photoinitiator in the present invention, the cationic dye-borate anion complex is usually used in an amount up to about 1% by weight based on the weight of the photopolymerizable or crosslinkable species in the photohardenable composition. More typically, the cationic dye-borate anion complex is used in an amount of about 0.2% to 0.5% by weight. While the cationic dye-borate anion complex can be used alone as the initiator, film speeds tend to be quite low and oxygen inhibition is observed.

The photosensitive composition may include a photoinitiator containing a thiol as described in commonly assigned U.S. Pat. No. 4,874,685 which is incorporated herein by reference. Representative examples of thiols useful in the present invention are mercaptobenzoxazole, ethoxymercaptobenzothiazole, mercaptobenzothiazole and 1-phenyl-5-mercaptotetrazole.

In accordance with one embodiment of the invention, a full color imaging system is provided in which the microcapsules are in three sets respectively containing cyan, magenta and yellow color formers sensitive to red, green, and blue light respectively. For good color balance, the visible-sensitive microcapsules are sensitive (λ max) at about 450 nm, 540 nm, and 650 nm, respectively. Such a system is useful with visible light sources in direct transmission or reflection imaging. They are useful in electronic imaging using digital printers, lasers or pencil light sources of appropriate wavelengths. Because digital imaging systems do not require the use of visible light, sensitivity can be extended into the UV and IR. Accordingly, the sensitivity can be extended into the IR and/or UV to spread the absorption spectra of the photoinitiators and avoid cross-sensitization.

The developer materials employed in carbonless paper technology are useful in the present invention. Illustrative examples are clay minerals such as acid clay, active clay, attapulgite, etc.; organic acids such as tannic acid, gallic acid, propyl gallate, etc.; acid polymers such as phenol-formaldehyde resins, phenol acetylene condensation resins, condensates between an organic carboxylic acid having at least one hydroxy group and formaldehyde, etc.; metal salts of aromatic carboxylic acids or derivatives thereof such as zinc salicylate, tin salicylate, zinc 2-hydroxy napththoate, zinc 3,5 di-tert butyl salicylate, zinc 3,5-di-(α-methylbenzyl) salicylate, oil soluble metals salts or phenol-formaldehyde novolak resins (e.g., see U.S. Pat. Nos. 3,672,935 and 3,732,120) such as zinc modified oil soluble phenol-formaldehyde resin as disclosed in U.S. Pat. No. 3,732,120, zinc carbonate etc. and mixtures thereof. The particle size of the developer material is important to obtain a high quality image. The developer particles should be in the range of about 0.2 to 3 microns and, preferably in the range of about 0.5 to 1.5 microns.

A suitable binder such as polyethylene oxide, polyvinyl alcohol, polyacrylamide, acrylic latices, neoprene emulsions, polystyrene emulsions, and nitrile emulsions, etc. may be mixed with the developer and the microcapsules, typically in an amount of about 1 to 8% by weight, to prepare a coating composition.

A preferred developer material is one which has excellent compatibility with the microcapsule slurry solution. Specific examples of useful developers, which have good stability include phenolic resins from Schenectady International, such as HRJ-4250 and HRJ-4542 and OR-1 developer from Sanko.

The microcapsules used in the present invention can be produced using known encapsulation techniques including coacervation, interfacial polymerization, polymerization of one or more monomers in an oil, as well as various melting, dispersing and cooling methods. The capsule forming material used in a given imaging system is selected based on the photosensitive composition present in the encapsulate. Thus, the formed capsule wall must be transmissive to the exposure radiation. Melamine-formaldehyde capsules are preferred.

The mean size of the capsules used in the present invention may vary over a broad range but generally ranges from approximately 1 to 10 microns. As a general rule, image resolution improves as the capsule size decreases with the caveat that if the capsule size is too small, the capsule may sit within incongruities in the support and the support may screen the capsules from exposure. Very small capsules may also fail to rupture upon the application of pressure. In view of the foregoing, it has been found that a preferred mean capsule size range is approximately 1 to 10 microns and particularly approximately 1 to 5 microns.

The photosensitive imaging media is then exposed to actinic radiation such that the microcapsules are image-wise exposed to form a latent image. As used herein, the term “actinic radiation” encompasses wavelengths in the ultraviolet spectral region, visible region and infrared spectral region. Typically, the actinic radiation source will be ultraviolet or visible wavelengths. The exposure to actinic radiation causes the encapsulated radiation curable composition to polymerize thereby preventing release of the image-forming chromogenic composition.

Typically, capsule rupture is effected by the application of pressure to the imaging sheet using pressure rollers. Although the present system has been described with reference to pressure development, alternative means of capsule rupture can also be used. For example, systems are envisioned in which the capsules are ruptured ultrasonically, by vibration, thermally, or by solvent.

Media stability may be improved by conditioning the components of the photosensitive imaging system (either the donor sheet or donor sheet and developer sheet or self-contained media) at a temperature of from about 15° C. to 40° C., preferably from about 30° C. to 40° C., most preferably around 35° C. The imaging media is typically stored at a relative humidity of from about 50-90% RH.

In accordance with another aspect of the present invention, the imaging media is developed at a temperature of from about 15° C. to 40° C., preferably from about 30° C. to 40° C., most preferably around 35° C., by providing a means for heating the imaging media to the desired temperature. Typically, this is achieved by providing a means for heating the imaging media before and/or during pressure developing. Means for heating the imaging media include conductive, convective and radiant heat. Specific means for heating the imaging media include use of an oven, heated developer rollers, heated forced air, IR, thermal head, heating strip or plate, etc.

In accordance with yet another aspect of the present invention, the imaging media is subjected to an elevated temperature after development to improve image development and increase density. Post development heat can be applied at any stage after development. For example, the imaging media can be heated to a temperature of from about 60° C. to 120° C. either before, during or after laminating the ID card substrate to the image by providing a means for heating the imaging media. Means for heating the imaging media include conductive, convective and radiant heat. Specific means for heating the imaging media include use of an oven, heated laminating rollers, heated forced air, IR, thermal head, heating strip or plate, etc. If a pressure sensitive adhesive is utilized as a laminating adhesive the post heating step is typically conducted after lamination. If the lamination adhesive is a thermally activated adhesive, then the lamination step will typically involve the application of heat to the imaging media during the lamination step to activate the adhesive, typically from about 70° C. to 125° or higher, preferably around 100° C. The heat applied to the media during lamination can also improve image development. Production of ID cards in accordance with the present invention may include more than one post development heating step.

Although the present invention has been described with reference to imaging materials in roll form, cut sheet imaging materials are also within the scope of the present invention. For example, precut developer sheets or precut self-contained sheets could be used. Furthermore, the die cut step could be eliminated if the cut sheets were of the appropriate size for the ID card or perforated to provide multiple cards per sheet which could subsequently be separated into individual ID cards.

The ID cards of the present invention may also incorporate other security features as is well known in the art. Examples of other security features that can be incorporated into the ID cards of the present invention include magnetic stripes, holograms, bar codes, fingerprints, microprinting, signatures, etc.

What is claimed is:

1. A method for producing identification cards comprising the steps of:
(a) providing a photosensitive imaging media comprising a developer material and a plurality of microcapsules encapsulating a photohardenable composition and a color former;
(b) image-wise exposing the plurality of microcapsules to actinic radiation to form a latent image;
(c) developing the image; and
(d) laminating an ID card substrate to the image to form an identification card comprising an image, wherein said image contains identifying information.

2. The method of claim 1 wherein said photosensitive imaging media is a self-contained imaging system comprising an imaging layer disposed between a pair of supports, wherein said imaging layer comprises the developer material and the plurality of microcapsules encapsulating a photohardenable composition and a color former.

3. The method of claim 1 wherein said photosensitive imaging media is a self-contained imaging system comprising an imaging layer on a support and a protective coating on said imaging layer wherein said imaging layer comprises the developer material and the plurality of microcapsules encapsulating a photohardenable composition and a color former.

4. The method of claim 1 wherein said photosensitive imaging media is a transfer system comprising a photosensitive donor sheet and a developer sheet, wherein said photosensitive donor sheet comprises the plurality of microcapsules encapsulating a photohardenable composition and a color former and said developer sheet comprises the developer material.

5. The method of claim 1 wherein the image is pressure developed at a temperature of from about 30° C. to 40° C.

6. The method of claim 1 wherein the ID card substrate is laminated to the image utilizing a thermally activated adhesive having an activation temperature of from about 70° C. to 125° C.

7. The method of claim 6 wherein said photosensitive imaging media includes said thermally activated adhesive and said adhesive overlies said image on the identification card.

8. The method of claim 1 wherein said step of providing a photosensitive imaging media comprises providing a photosensitive imaging media wherein said media has been conditioned at a temperature of from about 30° C. to 40° C.

9. The method of claim 1 wherein said developing step comprises subjecting said imaging media to pressure.

10. The method of claim 1 wherein said ID card substrate comprises a material selected from the group consisting of polyester, polycarbonate, polyvinyl chloride, polyethylene and polystyrene.

11. A method for producing identification cards comprising the steps of:
(a) image-wise exposing a photosensitive pressure-sensitive donor sheet to actinic radiation to form a latent image thereon,
(b) juxtaposing the donor sheet to a developer sheet,
(c) subjecting the juxtaposed donor sheet and developer sheet to pressure to develop the latent image thereby forming an image on the developer sheet,
(d) laminating an ID card substrate in registration with the image to the developer sheet to form a laminated article, and
(e) die cutting the laminated article to produce a finished ID card comprising an image, wherein said image contains identifying information.

12. The method of claim 11 further comprising:
(f) heating said image on the developer sheet to a temperature of from about 60° C. to 120° C. to promote image development.

13. The method of claim 11 wherein said photosensitive donor sheet comprises:
(a) a first set of microcapsules containing a cyan color former, said first set of microcapsules being sensitive to red light,
(b) a second set of microcapsules containing a magenta color former, said second set of microcapsules being sensitive to blue light; and
(c) a third set of microcapsules containing a yellow color former, said third set of microcapsules being sensitive to green light,
each of said microcapsules further containing a photohardenable composition such that full color images can be obtained.

14. The method of claim 12 wherein said first, second and third sets of microcapsules are sensitive to radiation selected from the group consisting of visible, ultraviolet and infrared.

15. The method of claim 11 wherein said step of image-wise exposing a photosensitive pressure-sensitive donor sheet to actinic radiation comprises image-wise exposing the donor sheet to actinic radiation using a plurality of LED's.

16. The method of claim 11 wherein said developer sheet comprises a transparent substrate.

17. The method of claim 16 wherein said transparent substrate comprises polyethylene terephthalate.

18. The method of claim 11 wherein said ID card substrate comprises a material selected from the group consisting of polyester, polycarbonate, polyvinyl chloride, polyethylene and polystyrene.

19. The method of claim 18 wherein said ID card substrate is precoated with a laminating adhesive.

20. The method of claim 11 wherein the image is pressure developed at a temperature of from about 30° C. to 40° C.

21. The method of claim 11 wherein the ID card substrate is laminated to the image utilizing a thermally activated adhesive having an activation temperature of from about 70° C. to 125° C.

22. The method of claim 21 wherein said developer sheet includes said thermally activated adhesive and said adhesive overlies said image on the identification card.

23. The method of claim 11 wherein said photosensitive pressure-sensitive donor sheet has been conditioned at a temperature of from about 30° C. to 40° C. prior to being image-wise exposed.

24. The method of claim 23 wherein the image is pressure developed at a temperature of from about 30° C. to 40° C.

25. A method for producing an identification card comprising:
translating identifying indicia into actinic radiation,
image-wise exposing a photosensitive donor sheet to said actinic radiation to form a latent image,
developing said latent image on a developer sheet thereby forming a developed image,
laminating an ID card substrate in registration with the developed image on the developer sheet, and
die cutting said developer sheet to produce an ID card wherein the developed image contains said identifying indicia.

26. The method of claim 25 wherein said step of image wise exposing a photosensitive donor sheet to actinic radiation comprises image wise exposing the donor sheet to actinic radiation using a plurality of LED's.

27. The method of claim 25 wherein said ID card substrate comprises a material selected from the group consisting of polyester, polycarbonate, polyvinyl chloride, polyethylene and polystyrene.

28. The method of claim 27 wherein said ID card substrate is precoated with a laminating adhesive.

29. The method of claim 25 wherein the image is pressure developed at a temperature of from about 30° C. to 40° C.

30. The method of claim 25 wherein the ID card substrate is laminated to the image utilizing a thermally activated adhesive having an activation temperature of from about 70° C. to 125° C.

31. The method of claim 25 further comprising subjecting said developed image to a temperature of from about 60° C. to 120° C. to improve image development.

32. An apparatus for producing identification cards comprising:
an exposure means for image-wise exposing a photosensitive donor sheet to actinic radiation to form a latent image thereon,
a pressure developer for pressure developing the latent image on the exposed donor sheet and forming an image on a developer sheet,
lamination means for laminating an ID card substrate in registration with the image on the developer sheet to form a laminated article; and
a die for die cutting the laminated article to produce a finished ID card, wherein said image comprises personalized information.

33. The apparatus of claim 32 further comprising a post development heating means for heating the image on the developer sheet to a temperature of from about 60° C. to 120° C. after pressure development of said image.

34. The apparatus of claim 32 wherein said exposure means comprises a plurality of LED's.

35. The apparatus of claim 32 wherein said developer sheet comprises a transparent substrate.

36. The apparatus of claim 35 wherein said transparent substrate comprises polyethylene terephthalate.

37. The apparatus of claim 32 wherein said ID card substrate comprises a material selected from the group consisting of polyester, polycarbonate, polyvinyl chloride, polyethylene and polystyrene.

38. The apparatus of claim 32 wherein said ID card substrate is precoated with a laminating adhesive.

39. The apparatus of claim 32 further comprising a means for heating said photosensitive donor sheet before or during pressure developing of the latent image.

40. The apparatus of claim 39 wherein said photosensitive donor sheet is heated to a temperature of from about 30° C. to 40° C.

41. The apparatus of claim 32 wherein said lamination means comprises a means for heating said ID card substrate and said developer sheet to a temperature of from about 70° C. to 125° C.
